(19) United States
(12) Patent Application Publication
(10) Pub. No.: US 2014/0042300 A1
(43) Pub. Date: Feb. 13, 2014

(54) IMAGE SENSOR AND COLUMN ANALOG-TO-DIGITAL CONVERTER THEREOF

(71) Applicant: NOVATEK MICROELECTRONICS CORP., Hsinchu (TW)

(72) Inventor: Jer-Hao Hsu, Hsinchu County (TW)

(73) Assignee: NOVATEK MICROELECTRONICS CORP., Hsinchu (TW)

(21) Appl. No.: 13/684,253

(22) Filed: Nov. 23, 2012

(30) Foreign Application Priority Data
Aug. 8, 2012 (TW) 101128617

(51) Int. Cl. H03M 1/12; H01L 27/146

(52) U.S. Cl. CPC H03M 1/124; H01L 27/146
USPC 250/208.1; 341/137

(57) ABSTRACT

An image sensor and a column analog-to-digital converter thereof are provided. The column analog-to-digital converter includes a counter providing a counter result, a ramp signal generator providing a ramp signal and a start signal, a sampling and comparing array, a first latch array, a second latch array, and an arithmetic unit. The sampling and comparing array outputs a plurality of brightness transformation signals according to the ramp signal, the start signal, and initial voltages and brightness voltages of a plurality of photosensitive pixels. The first and the second latch arrays latch the counter result in response to the brightness transformation signals and output a plurality of first brightness latch values during a first period and a plurality of second brightness latch values during a second period. The arithmetic unit calculates the brightness values of the photosensitive pixels according to the first brightness latch values and the second brightness latch values.

### CROSS-REFERENCE TO RELATED APPLICATION

This application claims the priority benefit of Taiwan application serial no. 101128617, filed on Aug. 8, 2012. The entirety of the above-mentioned patent application is hereby incorporated by reference herein and made a part of this specification.

### BACKGROUND OF THE INVENTION

1. Field of the Invention

The present invention generally relates to an image sensor and a column analog-to-digital converter thereof, in particular, to a low-noise image sensor and a column analog-to-digital converter thereof.

2. Description of Related Art

With the huge progress of digital technology and the rapid development of the Internet and multimedia applications in the recent years, analog images are expected to be converted to digital format for processing and transmission efficiency. Thus, an image sensor capable of converting analog images to digital images has gradually become significant in multimedia applications.

Generally speaking, an image sensor is composed of electronic components. The electrical specifications of the electronic components and circuits may approximate to ideal specifications and yet are incapable of absolutely reaching ideal specifications, so that the electronic components and circuits may result in noise, i.e. unexpected voltages or signals, and affect the digital image quality output from the image sensor. In regard to an amplifier, there exists an offset voltage between its two comparator input terminals (the offset does not exist in the ideal specifications), and therefore the comparator circuit composed of amplifiers may be affected by the offset voltage, which leads to an error in comparator results and correspondingly affect the accuracy of digital images. Thus, to minimize or to eliminate the noise due to the non-ideal specifications of the electronic components or circuits will be emphasized on the image sensor design.

### SUMMARY OF THE INVENTION

An image sensor and a column analog-to-digital converter thereof are provided, capable of minimizing the effect of the circuit noise to improve the accuracy of the detected brightness values.

According to an aspect, a column analog-to-digital converter suitable for a pixel array with a plurality of columns of photosensitive pixels is provided. The column analog-to-digital converter includes a counter, a ramp signal generator, a sampling and comparing array, a first latch array, a second latch array, and an arithmetic unit. The counter provides a counter result according to a clock signal. The ramp signal generator provides a ramp signal and a start signal according to the clock signal. The sampling and comparing array includes a plurality of sampling and comparing circuits, wherein each of the sampling and comparing circuits individually outputs a brightness transformation signal according to the ramp signal, the start signal, and an initial voltage and a brightness voltage of the photosensitive pixels within the corresponding column of the photosensitive pixels. The first latch array includes a plurality of first latches, wherein each of the first latches individually couples to the counter and latches the counter result as a first brightness latch value in response to the brightness transformation signal outputted from the corresponding sampling and comparing circuit during a first period. The second latch array includes a plurality of second latches, wherein each of the second latches individually couples to the counter and latches the counter result as a second brightness latch value in response to the brightness transformation signal outputted from the corresponding sampling and comparing circuit during a second period different from the first period. The arithmetic unit is coupled to the first latch array and the second latch array for receiving the first brightness latch value from each of the first latches and the second brightness latch value from each of the second latches, and calculating a brightness value of the corresponding column of the photosensitive pixels according to the received first brightness latch value and the received second brightness latch value.

In accordance with an embodiment of the present invention, the first period is a first phase period of a phase signal and the second period is a second phase period of the phase signal.

In accordance with an embodiment of the present invention, the arithmetic unit calculates a sum of the received first brightness latch value and the received second brightness latch value as the brightness value of the corresponding column of the photosensitive pixels.

In accordance with an embodiment of the present invention, the arithmetic unit calculates an average of the received first brightness latch value and the received second brightness latch value as the brightness value of the corresponding column of the photosensitive pixels.

In accordance with an embodiment of the present invention, the arithmetic unit includes a plurality of sub-arithmetic units, wherein each of the sub-arithmetic units is coupled to the corresponding first latch and the corresponding second latch, and the sub-arithmetic units parallel calculate the brightness values of the columns of the photosensitive pixels according to the first brightness latch values from the first latches and the second brightness latch values from the second latches in the same time period.

In accordance with an embodiment of the present invention, the arithmetic unit sequentially calculates the brightness value of each column of the photosensitive pixels individually according to the first brightness latch value from one of the first latches and the second brightness latch value from one of the two latches respectively in different time periods.

In accordance with an embodiment of the present invention, each of the sampling and comparing converters includes a first comparator switch, a second comparator switch, a first capacitor, a second capacitor, an amplifier, a signal exchanger, a first sampling switch, and a second sampling switch. The first comparator switch includes a first terminal coupled to the ramp signal and a second terminal. The second comparator switch includes a first terminal coupled to the start signal and a second terminal. The first capacitor includes a first terminal coupled to the second terminal of the first comparator switch and the brightness voltage, and a second terminal. The second capacitor includes a first terminal coupled to the second terminal of the second comparator switch and the initial voltage, and a second terminal. The amplifier includes a first comparator input terminal, a second comparator input terminal, a first comparator output terminal, and a second comparator output terminal, wherein the brightness transformation signal is generated according to the voltage level of at least one of the first comparator output terminal and the second comparator output terminal. The signal exchanger is coupled between the first capacitor, the second capacitor, and the amplifier for controlling the second terminals of the first capacitor and the second capacitor whether to be coupled to the first comparator input terminal and the second comparator input terminal of the amplifier respectively or to be coupled to the second comparator input terminal or the first comparator input terminal of the amplifier respectively. The first sampling switch is coupled between the first comparator input terminal of the amplifier and a reference voltage. The second sampling switch is coupled between the second comparator input terminal of the amplifier and the reference voltage.

In accordance with an embodiment of the present invention, the column analog-to-digital converter further includes a brightness voltage switch and an initial voltage switch. The brightness voltage switch is coupled between the brightness voltage and the first terminal of the first capacitor. The initial voltage switch is coupled between the initial voltage and the first terminal of the second capacitor.

In accordance with an embodiment of the present invention, the brightness voltage switch and the initial voltage switch are turned on in sequence during a sampling period within the first phase period of a phase signal and turned off during comparing periods within the first phase period of the phase signal and the second phase period of the phase signal.

In accordance with an embodiment of the present invention, the signal exchanger couples the second terminal of the first capacitor and the second terminal of the second capacitor to the first comparator input terminal and the second comparator input terminal of the amplifier respectively during the comparing period within the first phase period of the phase signal, and the signal exchanger couples the second terminal of the first capacitor and the second terminal of the second capacitor to the second comparator input terminal and the first comparator input terminal of the amplifier respectively during the comparing period within the second phase period of the phase signal.

In accordance with an embodiment of the present invention, the first and the second sampling switches are turned on and the first and the second comparator switches are turned off during the sampling period within the first phase period of the phase signal prior to the comparing period of the first phase period; the first and the second sampling switches are turned off and the first and the second comparator switches are turned on during the comparing periods within the first phase period and of the second phase period of the phase signal.

In accordance with an embodiment of the present invention, the first comparator output terminal outputs a first level and the second comparator output terminal outputs a second level when the voltage level of the first comparator input terminal is higher than that of the second comparator input terminal, and the first comparator output terminal outputs the second level and the second comparator output terminal outputs the first level when the voltage level of the first comparator input terminal is lower than or equal to that of the second comparator input terminal.

In accordance with an embodiment of the present invention, each of the sampling and comparing circuits further includes a transformation signal generating unit coupled between the first comparator output terminal and the second comparator output terminal of the amplifier and a comparator output terminal of the sampling and comparing circuit, and outputs the brightness transformation signal according to the voltage levels of the first comparator output terminal and the second comparator output terminal.

In accordance with an embodiment of the present invention, the transformation signal generating unit switches the voltage level of the brightness transformation signal when the voltage levels of the first comparator input terminal and the second comparator input terminal are substantially equal.

In accordance with an embodiment of the present invention, the transformation signal generating unit includes a RS latch. The RS latch includes a first latch input terminal coupled to the first comparator output terminal, a second latch input terminal coupled to the second comparator output terminal, a first latch output terminal, and a second latch output terminal.

In accordance with an embodiment of the present invention, the transformation signal generating unit further includes a logic unit. The logic unit includes a first logic input terminal coupled to the first latch output terminal, a second logic input terminal coupled to the second latch output terminal, and a logic output terminal, wherein the logic unit switches the voltage level of the logic output terminal based on the voltage levels of the first logic input terminal and the second logic input terminal.

In accordance with an embodiment of the present invention, the logic unit includes a NOR gate, wherein a plurality of input terminals of the NOR gate are individually coupled to the first logic input terminal and the second logic input terminal, and an output terminal of the NOR gate is coupled to the logic output terminal.

In accordance with an embodiment of the present invention, the transformation signal generating unit includes a signal switch. The signal switch includes a first switch input terminal coupled to the first comparator output terminal of the amplifier, a second switch input terminal coupled to the second comparator output terminal of the amplifier, and an exchange output terminal, wherein the exchange output terminal is coupled to the first switch input terminal during the first period and is coupled to the second switch input terminal during the second period.

In accordance with an embodiment of the present invention, each of the sampling and comparing circuits includes a signal exchanger and an amplifier. The signal exchanger includes a first exchange input terminal, a second exchange input terminal, a first exchange output terminal, and a second exchange output terminal, wherein the first exchange input terminal and the second exchange input terminal are coupled to the first exchange output terminal and the second exchange output terminal respectively under a first mode, and the first exchange input terminal and the second exchange input terminal are coupled to the second exchange output terminal and the first output exchange terminal respectively under a second mode. The amplifier includes a first comparator input terminal and a second comparator input terminal coupled to the first exchange output terminal and the second exchange output terminal respectively and also includes a first comparator output terminal and a second comparator output terminal, wherein the brightness transformation signal is generated based on at least one of the voltage levels of the first comparator output terminal and the second comparator output terminal. The signal exchanger is operated under the first mode during the sampling period within the first period, so that the first comparator input terminal and the second comparator input terminal coupled to the brightness voltage and the initial voltage respectively. The signal exchanger is operated under the first mode during the comparing period within the first period, so that the first comparator input terminal and the second comparator input terminal coupled to the ramp signal and the start signal respectively. The signal exchanger is operated under the second mode during the comparing period within the second period, so that the first comparator input terminal and the second comparator input terminal coupled to the start signal and the ramp signal respectively.

In accordance with an embodiment of the present invention, each of the sampling and comparing circuits further includes a first capacitor, a second capacitor, a first comparator switch and a second comparator switch. The first capacitor includes a first terminal and a second terminal, wherein the second terminal is coupled to the first exchange input terminal. The second capacitor includes a first terminal and a second terminal, wherein the second terminal is coupled to the second exchange input terminal. The first comparator switch coupled between the ramp signal and the first terminal of the first capacitor. The second comparator switch coupled between the start signal and the first terminal of the second capacitor.

In accordance with an embodiment of the present invention, each of the sampling and comparing circuits further includes a brightness voltage switch and an initial voltage switch. The brightness voltage switch coupled between the brightness voltage and the first terminal of the first capacitor. The initial voltage switch coupled between the initial voltage and the first terminal of the second capacitor.

In accordance with an embodiment of the present invention, each of the sampling and comparing circuits further includes a first sampling switch and a second sampling switch. The first sampling switch is coupled between the first comparator input terminal of the amplifier and a reference voltage. The second sampling switch is coupled between the second comparator input terminal of the amplifier and the reference voltage.

In accordance with an embodiment of the present invention, the sampling and comparing array is operated under the first mode and the second mode during the first period and the second period respectively, wherein the brightness transformation signal and the brightness voltage have different functional relationships under the first mode and the second mode.

According to another aspect, an image sensor including a pixel array and a column analog-to-digital converter as described above is also provided. The pixel array includes a plurality of columns of photosensitive pixels. The column analog-to-digital converter as described above is coupled to the pixel array.

Based upon above description, the image sensor and the column analog-to-digital converter thereof in the embodiments of the present invention generate a brightness transformation signal according to an initial voltage and a brightness voltage of the photosensitive pixels within the corresponding column and a ramp signal and a start signal provided by a ramp signal generator. The first latch latches a counter result provided by the counter to output a first brightness latch value according to the corresponding brightness transformation signal during a first period; the second latch latches a counter result provided by the counter to output a second brightness latch value according to the corresponding brightness transformation signal during a second period. The arithmetic unit calculates a brightness value of the photosensitive pixel of the corresponding column according to the corresponding first brightness latch value and the corresponding second brightness latch value. Therefore, the effect of the circuit noise can be minimized to improve the accuracy of the detected brightness values.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a system block diagram illustrating an image sensor in accordance with an embodiment of the invention.

FIG. 2A is a schematic illustrating the sampling and comparing circuits in accordance with an embodiment of the invention of FIG. 1.

FIG. 2B is a schematic illustrating the driving waveform of the sampling and comparing circuit in accordance with the embodiment of the invention in FIG. 2A.

FIG. 3A is a schematic illustrating the sampling and comparing circuits in accordance with another embodiment of the invention of FIG. 1.

FIG. 3B is a schematic illustrating the driving waveform of the sampling and comparing circuit in accordance with the embodiment of the invention in FIG. 3A.

FIG. 4A is a schematic illustrating the sampling and comparing circuits in accordance with another embodiment of the invention of FIG. 1.

FIG. 4B is a schematic illustrating the driving waveform of the sampling and comparing circuit in accordance with the embodiment of the invention in FIG. 4A.

FIG. 5 is a schematic illustrating the sampling and comparing circuits in accordance with another embodiment of the invention of FIG. 1.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

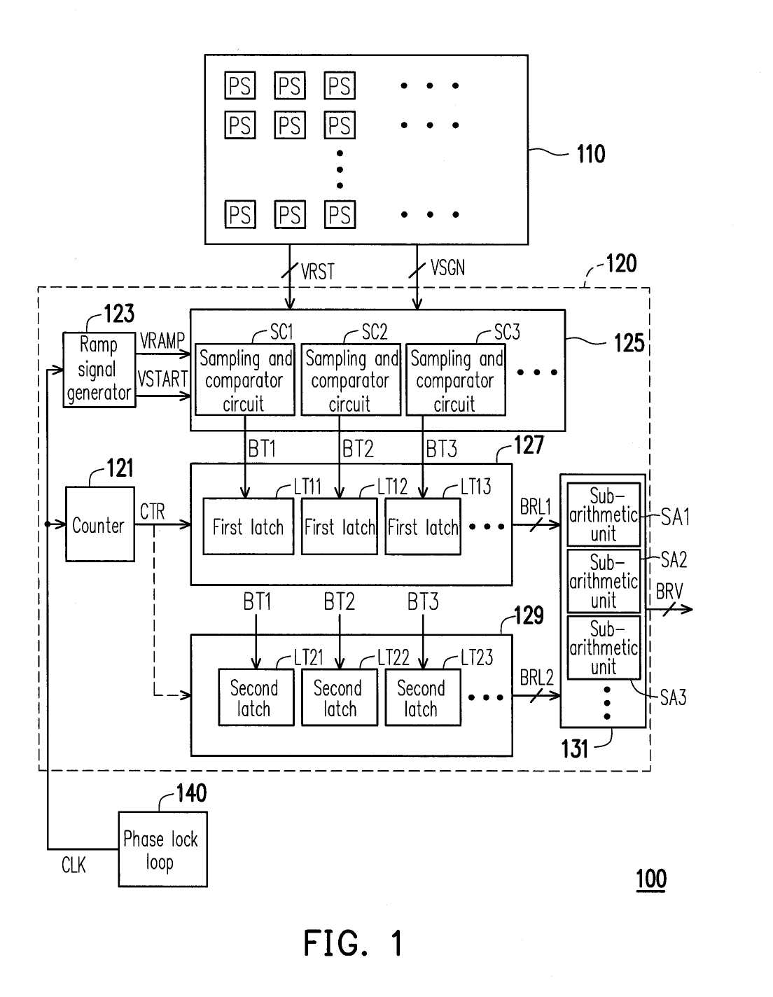

FIG. 1 is a system block diagram illustrating an image sensor according to an embodiment of the invention. Referring to FIG. 1, the image sensor 100 of the embodiment includes a pixel array 110, a column analog-to-digital converter 120, and a phase lock loop 140. The pixel array 110 includes photosensitive pixels PS arranged in a plurality of columns (n) and a plurality of rows (m), wherein each of the photosensitive pixels PS provides an initial voltage VRST and a brightness voltage VSGN. The pixel array 110 is outputting signals row by row, which the n initial voltages VRST and n brightness voltages provided by n pixels within a column may be outputted during every time. The phase lock loop 140 provides a clock signal CLK. The column analog-to-digital converter 120 is coupled to the pixel array 110 for receiving the initial voltages VRST and the brightness voltages VSGN provided by the photosensitive PS and is also coupled to the lock loop 140 for receiving the clock signal CLK. The column analog-to-digital converter 120 calculates brightness values of the photosensitive pixels PS according to the clock signal CLK, initial voltages VRST and brightness voltages VSGN of the photosensitive pixels.

In the present embodiment, the column analog-to-digital converter 120 includes a counter 121, a ramp signal generator 123, a sampling and comparing array 125, a first latch array 127, a second latch array 129, and an arithmetic unit 131. The counter 121 is coupled to the phase lock loop 140 for receiving the clock signal CLK and executes the counting according to the clock signal CLK for providing a counter result CTR. The ramp signal generator 123 is coupled to the phase lock loop 140 for receiving the clock signal CLK, provides a ramp signal VRAMP according to the clock signal CLK, and provides a start signal VSTART. The voltage level of the ramp signal VRAMP may be design to be increased or decreased with time and may correspond to the counter result CTR from the counter 121. The start signal VSTART may be design to be a direct current voltage, wherein the voltage level of the start signal VSTART is the initial voltage level of the increasing ramp signal VRAMP or the decreasing ramp signal VRAMP.

The sampling and comparing array 125 includes a plurality of sampling and comparing circuits, such as SC1˜SC3 and so on. Each of the sampling and comparing circuits, such as SC1˜SC3, is coupled to the ramp signal generator 123 for receiving the ramp signal VRAMP and the start signal VSTART, and is also coupled to a photosensitive pixel PS within the corresponding column of the photosensitive pixels PS for receiving the corresponding initial voltage VRST and the corresponding bright ness voltage VSGN. Each of the sampling and comparing circuits, such as SC1˜SC3, outputs a brightness transformation signal, such as BT1˜BT3, according to the ramp signal VRAMP, the start signal VSTART, the received initial voltage VRST, and the received brightness voltage VSGN.

Additionally, the sampling and comparing circuit SCi, where i=1, 2, . . . n, may be operated under a first model and a second mode. Under the first mode and the second mode, the represented digital code codeᵢ of the brightness transformation signal BTi and the voltage level of the brightness voltage VSGN have different functional relationships. Mathematically speaking, the represented digital codes code; of the brightness transformation signal BTi and the voltage level of the brightness voltage VSGN has a first functional relationship under the first mode as codeᵢ=f₁_{ⁱ}(VSGN). The represented digital codes codeᵣ of the brightness transformation signal BTi and the voltage level of the brightness voltage VSGN forms a second function relationship under the second mode as codeᵢ=g₁_{ⁱ}(VSGN).

In a particular embodiment, the sampling and comparing circuit SCi may switch the voltage level of the transformation signal BTi when the approximation of the voltage difference of the ramp signal VRAMP and the start signal VSTART and the voltage difference between the brightness voltage VSGN and the initial voltage VRST is detected. In other words, the represented digital codes code₁ of the brightness transformation signal BTi is defined by the switching time of the voltage level of the brightness transformation signal BTi, wherein the digital codes corresponds to the voltage difference between the brightness voltage VSGN and the first voltage VRST. The mathematical representation can be expressed as follows:

codeᵢ=f₁_{ⁱ}(VSGN)=F₁_{ⁱ}(VRST−VSGN) under the first mode

codeᵢ=g₁_{ⁱ}(VSGN)=G₁_{ⁱ}(VRST−VSGN) under the second mode

More preferably, all of the sampling and comparing circuits SC1˜SCn may operate under the first mode during a first period and may operate under the second mode during a second period different from the first period. The sampling and comparing circuit SCi may be controlled by a received phase signal φ, wherein the first period is a first phase period of the phase signal φ (e.g. the period at a high voltage level) and the second period is a second phase period of the phase signal (e.g. the period at a low voltage level).

The first latch array 127 includes a plurality of first latches, such as LT11˜LT13. Each of the first latches, such as LT11˜LT13, is coupled to the counter 121 for receiving a counter result CTR, and is also coupled to the corresponding sampling and comparing circuit, such as SC1˜SC3, for receiving the corresponding brightness transformation signal, such as BT1˜BT3. During the first period, the counter result CTR from the counter 121 may be provided to the first latches, such as LT11˜LT13, and the first latches, such as LT11˜LT13, timely latches the counter result CTR as a first brightness latch value BRL1, e.g. includes BRL11˜BR1n, in response to the corresponding brightness transformation signal, such as BT1˜BT3.

For example, assuming the counter result CTR generated from the counter 121 increases or decreases with time, each of the first latches LT1j, where j=1, 2, . . . , n, may latch the counter result CTR as the corresponding first brightness latch value BRL1j when the changed counter result CTR is equal the value represented by the corresponding first brightness latch value BRL1j. In a particular embodiment, the switching time of the voltage level of the brightness transformation BTi generated from the sampling and comparing circuit SCi, where i=1, 2, . . . , n, represents the brightness voltage VSGN of the corresponding pixel. The first latches LT1j within the first latch array 127 responds to the switching operation of the voltage level of the brightness transformation signal BTi, and timely latches the counter result CTR as the first brightness latch value BRL1j. Mathematically speaking, all of the sampling and comparing circuits SC1˜SCn may operate under the first mode during the first period. If the represented digital code code₁ of the first brightness latch value BRL1j is fitted in with codeᵢ=f₁_{ⁱ}(VSGN)=F₁_{ⁱ}(VRST−VSGN), the first brightness latch value BRL1j can be expressed as the same digital code codeᵢ.

The second latch array 129 includes a plurality of second latches, such as LT21˜LT23. Each of the second latches, such as LT21˜LT23, is coupled to the counter 121 for receiving a counter result CTR, and is also coupled to the corresponding sampling and comparing circuit, such as SC1˜SC3, for receiving the corresponding brightness transformation signal, such as BT1˜BT3. During the second period, the counter result CTR from the counter 121 may be provided to the second latches within the second latch array 129, such as LT21˜LT23, and the second latch array 129, such as LT21˜LT23, latches the counter result CTR as a second brightness latch value BRL2, e.g. includes BRL21˜BR2n, in response to the corresponding brightness transformation signal, such as BT1˜BT3.

For example, assuming the counter result CTR generated from the counter 121 increases or decreases with time, each of the second latches LT2j, where j=1, 2, . . . , n, may latch the counter result CTR as the corresponding second brightness latch value BRL2j when the changed counter result CTR is equal the value represented by the corresponding second brightness latch value BRL2j. In a particular embodiment, the switching time of the voltage level of the brightness transformation BTi generated from the sampling and comparing circuit SCi, where i=1, 2, . . . , n, represents the brightness voltage VSGN of the corresponding pixel. The second latches LT2i within the second latch array 129 responds to the switching operation of the voltage level of the brightness transformation signal BTi, and timely latches the counter result CTR as the second brightness latch value BRL2i. Mathematically speaking, all of the sampling and comparing circuits SC1˜SCn may operate under the second mode during the second period. If the represented digital code codeᵢ of the second brightness latch value BRL2i is fitted in with codeᵢ=g₁_{ⁱ}(VSGN)=G₁_{ⁱ}(VRST−VSGN), the second brightness latch value BRL2i can be expressed as the same digital code codeᵢ.

Noteworthily, the relationship between the voltage level of the brightness transformation signal. BTi and trigger of the first latches and the second latches may be design in various ways. For example, in some particular embodiments, the sampling and comparing circuit SCi may switch the voltage level of the brightness transformation signal BTi to form a rising edge or a falling edge, and the first latch such as LT11˜LT13 and the second latch such as LT21˜LT23 may be correspondingly designed to be double-edge triggered. In other embodiments, the sampling and comparing circuit SCi may switch the voltage level of the brightness transformation signal BTi to form a rising edge, and the first latch such as LT11˜LT13 and the second latch such as LT21˜LT23 may be correspondingly designed to be rising edge triggered. In further other embodiments, the sampling and comparing circuit SCi may switch the voltage level of the brightness transformation signal BTi to form a falling edge, and the first latch such as LT11˜LT13 and the second latch such as LT21˜LT23 may be correspondingly designed to be falling edge triggered. Additionally, under the condition of the sampling and comparing circuit SCi is designed to switch the voltage level of the brightness transformation signal BTi to form a positive pulse, the first latch such as LT11˜LT13 and the second latch such as LT21˜LT23 may be correspondingly designed to be high level triggers. Reversely, under the condition of the sampling and comparing circuit SCi is designed to switch the voltage level of the brightness transformation signal BTi to form a negative pulse, the first latch such as LT11˜LT13 and the second latch such as LT21˜LT23 may be designed to be low level triggers.

The arithmetic unit 131 is coupled to the first latch array 127 and the second latch array 129 for receiving the first latch value BRL1 from each of the first latches such as LT11˜LT13 and the second latch value BRL2 from each of the second latches such as LT21˜LT23, and calculates the brightness value BRV of each photosensitive pixel PS according to the received first brightness latch value BRL1 and the received second brightness latch value BRL2.

To sum up above, each of the sampling and comparing circuits such as SC1˜SC3 outputs a brightness transformation signal such as BT1˜BT3 according to ramp signal VRAMP, the start signal VSTART, and the initial voltage VRST and the brightness voltage VSGN of a photosensitive pixel PS within the corresponding column, and first latch array 127 and the second latch array 129 generate the first brightness latch value BRL1 and the second brightness latch value BRL2 respectively according to the brightness transformation signal such as BT1˜BT3, the arithmetic unit 131 is able to calculate the brightness values BRV of the photosensitive pixels PS according to the first brightness latch value BRL1 and the second brightness latch value BRL2. Mathematically speaking, the brightness value of the photosensitive pixel PS within the ith column can be expressed as BRVi=H(F₁_{ⁱ}(VRST−VSGN), G₁_{ⁱ}(VRST−VSGN)), where H denotes the calculation function executed by the arithmetic unit.

The arithmetic unit 131 may calculate the brightness value BRV of the photosensitive pixel PS within the corresponding column according to first brightness latch value BRL1 and the second brightness latch value BRL2 in various ways. For example, under the condition of the number of bits of the first brightness latch value BRL1, the number of bits of second brightness latch value BRL2 and the number of bits of the brightness value BRV are the same, the arithmetic unit 131 is designed for calculating an average of the received first brightness latch value BRL1 and the received second brightness latch value BRL2 as the brightness value BRV of the corresponding column of the photosensitive pixel PS. Mathematically speaking, the brightness value BRVi of the photosensitive pixel PS within the i^{th} column can be expressed as BRVi=(F₁_{ⁱ}(VRST−VSGN), G₁_{ⁱ}(VRST−VSGN))/2. In another example, under the condition of the number of bits of the first brightness latch value BRL1 and the number of bits second brightness latch value BRL2 are equal to the number of bits of the brightness value BRV minus 1, the arithmetic unit 131 is designed for calculating a sum of the received first brightness latch value BRL1 and the received second brightness latch value BRL2 as the brightness value BRV of the corresponding column of the photosensitive pixel PS. Mathematically speaking, the brightness value BRVi of the photosensitive pixels PS within the i^{th} column can be expressed as BRVᵢ=(F₁_{ⁱ}(VRST−VSGN)+G₁_{ⁱ}(VRST−VSGN)).

In this embodiment, the calculation of the arithmetic unit 131 is parallel processing. In other words, the arithmetic unit 131 may be designed in parallel calculates the brightness values BRV1˜BRVn of n columns of the photosensitive pixels PS according to the first brightness latch values from the first latches such as BRL11˜BRL13 and the second brightness latch values from the second latches such as BRL21˜BRL23 simultaneously.

In order to reach the above objectives, as illustrated in the embodiment of FIG. 1, the arithmetic unit 131 may include a plurality of sub-arithmetic units such as SA1˜SA3. Each of the sub-arithmetic units such as SA1˜SA3 is coupled to the corresponding first latch such as LT11˜LT13 and the corresponding second latch such as LT21˜LT23 for individually receiving the corresponding first brightness latch value BRL1 and the second brightness latch value BRL2. Moreover, the sub-arithmetic unit such as SA1˜SA3 may parallel calculate the brightness values BRV1˜BRVn of the columns of the photosensitive pixels according to the first brightness latch values BRL1 from the first latches such as BRL11˜BRL13 and the second brightness latch values BRL2 from the second latches such as BRL21˜BRL23 simultaneously.

It is noteworthy, however, that in another embodiment (unillustrated), the calculation of the arithmetic unit 131 may be achieved by batch processing; that is, the arithmetic unit 131 calculates the brightness value BRV of a photosensitive pixel within the corresponding column of the photosensitive pixels PS one by one. Thus, the arithmetic unit 131 sequentially calculates the brightness BRV of n photosensitive pixels within a row. In other words, the arithmetic unit 131 calculates the brightness value BRVi of a photosensitive pixel PS within the i^{th} column based on the first brightness latch value such as BRL1i of the first latch LT1i (where i=1, 2, . . . , n) and the second brightness latch value such as BRL2i of the second latch LT2i (where i=1, 2, . . . , n) in every calculation.

As will be described in the embodiments in detail hereinafter, via a proper design of the sampling and comparing circuit SC, F₁_{ⁱ}(VRST−VSGN) may be designed to be positively correlated with the voltage offset level of an amplifier in the sampling and comparing circuit SCi, while G₁_{ⁱ}(VRST−VSGN) may be negatively correlated with the voltage offset level. Then the error of the brightness value BRV caused by the voltage offset level of the amplifier may be eliminated by proper calculations performed by the arithmetic unit 131.

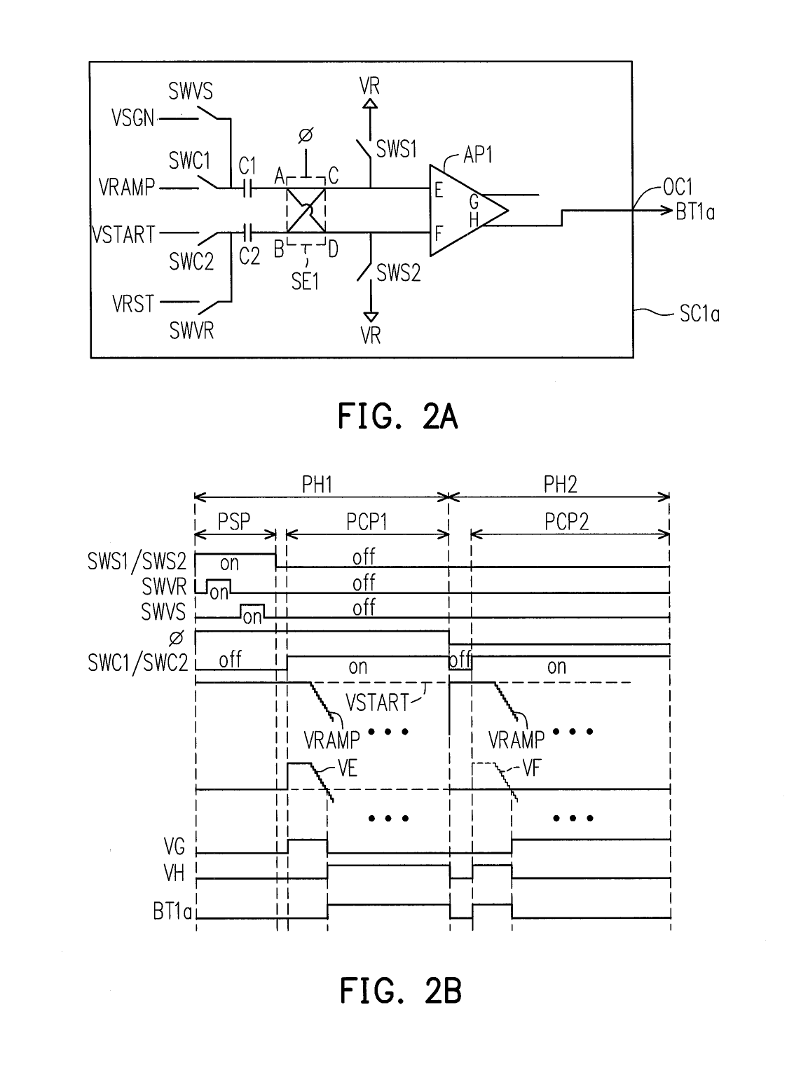

FIG. 2A is a schematic illustrating a sampling and comparing circuits in accordance with an embodiment of the invention in FIG. 1. Referring to FIG. 1 and FIG. 2A, in the present embodiment, the sampling and comparing circuit is denoted as SC1a and the brightness transformation signal generated by which is denoted as BT1a, wherein SC1a and BT1a may respectively be any sampling and comparing circuit SCi and the brightness transformation signal BTi generated by which, where i=1, 2, . . . n, in FIG. 1.

In the present embodiment, when the approximation of the voltage difference of the ramp signal VRAMP and the start signal VSTART and the voltage difference between the brightness voltage VSGN and the initial voltage VRST is detected, the sampling and comparing circuit SC1a is designed for switching the voltage level of the transformation signal BTi, which triggers the first latch such as LT11˜LT13 within the first latch array 127 latches the counter result CTR as the first brightness latch value BRL1 and which also triggers the second latch such as LT21˜LT23 within the second latch array 129 latches the counter result CTR as the second brightness latch value BRL2.

Referring to FIG. 2A, the sampling and comparing circuit SC1a includes a first comparator switch SWC1, a second comparator switch SWC2, a first capacitor C1, a second capacitor C2, an amplifier AP1, a signal exchanger SE1, a first sampling switch SWS1, a second sampling switch SWS2, a brightness voltage switch SWVS, and an initial voltage switch SWVR. The signal exchanger SE1 includes a first switch input terminal A, a second switch input terminal B, a first exchange output terminal C, and a second exchange output terminal D. The amplifier AP1 includes a first comparator input terminal E, a second comparator input terminal F, a first comparator output terminal G, and a second comparator output terminal H, wherein the second comparator output terminal H is directly served as an output terminal OC1 of the comparator circuit SC1a and outputs a voltage VH as the brightness transformation signal BT1a.

The first comparator switch SWC1 includes a first terminal coupled to the ramp signal VRAMP and a second terminal coupled to a first terminal of the first capacitor C1; that is, the first comparator switch SWC1 is coupled between the ramp signal VRAMP and the first terminal of the first capacitor C1. The brightness voltage switch SWVS includes a first terminal coupled to the brightness voltage VSGN and a second terminal coupled to the first terminal of the first capacitor C1; that is, the brightness voltage switch SWVS is coupled between the brightness voltage VSGN and the first terminal of the first capacitor C1. Under this arrangement, the first terminal of the first capacitor C1 is coupled to the ramp signal VRAMP via the first comparator switch SWC1 or coupled to the brightness voltage VSGN via the brightness voltage switch SWVS. Additionally, a second terminal of the first capacitor C1 is coupled to the first switch input terminal A of the signal exchanger SE1.

Similarly, the second comparator switch SWC2 includes a first terminal coupled to the start signal VSTART and a second terminal coupled to a first terminal of the second capacitor C2; that is, the second comparator switch SWC2 is coupled between the start signal VSTART and the first terminal of the second capacitor C2. The initial voltage switch VRST includes a first terminal coupled to the initial voltage VRST and a second terminal coupled to the first terminal of the second capacitor C2; that is, the initial voltage switch SWVR is coupled between the initial voltage VRST and the first terminal of the second capacitor C2. Under this arrangement, the first terminal of the second capacitor C2 is coupled to the start signal VSTART via the second comparator switch SWC2 or coupled to the initial voltage VRST via the initial voltage switch SWVR. Additionally, a second terminal of the second capacitor C2 is coupled to the second switch input terminal B of the signal exchanger SE1.

The first exchange output terminal C of the signal exchanger SE1 is coupled to the first comparator input terminal E of the amplifier AP1, and the second exchange output terminal D of the signal exchanger SE1 is coupled to the second comparator input terminal F of the amplifier AP1; that is, the signal exchanger SE1 is coupled between the second terminal of the first capacitor C1, the second terminal of the second capacitor C2, the first comparator input terminal E and the second comparator input terminal F of the amplifier AP1.

Moreover, the signal exchanger SE1 may be, for example, controlled by the phase signal φ which results in different input-output relations. When the phase signal φ is within the first phase period, i.e. the sampling and comparing circuit SC1a is operated under the first mode, the signal exchanger SE1 controls the first switch input terminal A to couple to the first exchange output terminal C and the second switch input terminal B to couple to the second exchange input terminal D based on the phase signal φ, that is, the second terminal of the first capacitor C1 is coupled to the first comparator input terminal E of the amplifier AP1, and the second terminal of the second capacitor C2 is coupled to the second comparator input terminal F of the amplifier AP1. When the phase signal φ is within the second phase period, i.e. the sampling and comparing circuit SC1a is operated under the second mode, the signal exchanger SE1 controls the first switch input terminal A to couple to the second exchange output terminal D and the second switch input terminal B to couple to the first exchange output terminal C based on the phase signal φ; that is, the second terminal of the first capacitor C1 is coupled to the second comparator input terminal F of the amplifier AP1, and the second terminal of the second capacitor C2 is coupled to the first comparator input terminal E of the amplifier AP1.

The first sampling switch SWS1 is coupled between the first comparator input terminal E of the amplifier AP1 and a reference voltage VR. The second sampling switch SWS2 is coupled between the second comparator input terminal F of the amplifier AP1 and the reference voltage VR, wherein the reference voltage VR may be high voltage level or low voltage level, which is not restricted in the present invention.

The amplifier AP1 determines the voltage levels of the first comparator output terminal G and the second comparator output terminal H based on the voltage levels of the first comparator input terminal E and the second comparator input terminal F. For example, the first comparator output terminal G outputs a first level (e.g. a high voltage level) and the second comparator output terminal H outputs a second level (e.g. a low voltage level) when the voltage level of the fist comparator input terminal E is higher than the voltage level of the second comparator input terminal F, and the first comparator output terminal G outputs the second level and the second comparator output terminal H outputs the first level when the voltage level of the first comparator input terminal E is lower than or equal to that of the second comparator input terminal F.

In the present embodiment, a circuit structure composed of the first capacitor C1, the second capacitor C2, the first sampling switch SWS1, the second sampling switch SWS2, the brightness voltage switch SWVS, and the initial voltage switch SWVR may be viewed as a correlated double sampling (CDS) circuit, wherein the first capacitor C1 is used for sampling the brightness voltage VSGN and the second capacitor C2 is used for sampling the initial voltage VRST. A circuit structure composed of the signal exchanger SE1, the first sampling switch SWS1, the second sampling switch SWS2, and the amplifier AP1 may be viewed as a comparator circuit for comparing the voltage levels of the first exchange output terminal C and the second exchange output terminal D, and generates the brightness transformation signal BT1a based on the comparison result.

During the operation of the sampling and comparing circuit SC1a, the CDS circuit firstly samples a voltage from the brightness voltage VSGN and the initial voltage VRST. Then, assuming the sampling and comparing circuit SC1a is operated under the first mode, based on the comparison between the voltage levels of the first exchange output terminal C and the second exchange output terminal D, the comparator circuit switches the voltage level of the brightness transformation BT1a when the voltage difference of the ramp signal VRAMP and the start signal VSTART is approximate or equal to the voltage difference between the brightness voltage VSGN and the initial voltage VRST. Next, the sampling and comparing circuit SC1a is switched to operate under the second mode. Similarly, based on the comparison between the voltage levels of the first exchange output terminal C and the second exchange output terminal D, the comparator circuit switches the voltage level of the brightness transformation BT1a when the voltage difference of the ramp voltage VRAMP and the start signal VSTART is approximate or equal to the voltage difference between the brightness voltage VSGN and the initial voltage VRST.

In the present embodiment, the voltage level relation between the brightness voltage VSGN and the initial voltage VRST is designed to be the voltage across the first capacitor C1 is higher than the voltage across the second capacitor C2 after the sampling process, that is, the voltage level of the first switch input terminal A is higher than that of the second switch input terminal B. Under such condition, the ramp signal VRAMP may be correspondingly designed to be decreased for gradually lowering the voltage level of the first switch input terminal A. Thus, the most proximate voltage levels of the first switch input terminal A and the second switch input terminal B occur at the moment of the voltage level of the first switch input terminal A being lower than the voltage level of the second switch input terminal B. Meanwhile, the high-low relation between the voltage levels of the first exchange output terminal C and the second exchange output terminal D may be exchanged, which leads to an exchange of the voltage levels of the first comparator output terminal G and the second comparator output terminal H, and means that the voltage difference of the ramp signal VRAMP and the start signal VSTART is approximate or equal to the voltage difference between the brightness voltage VSGN and the initial voltage VRST at this moment.

However, in other embodiments, the voltage level relation between the brightness voltage VSGN and the initial voltage VRST is designed to be the voltage across the first capacitor C1 is lower than the voltage across the second capacitor C2 after the sampling process, that is, the voltage level of the first switch input terminal A is lower than that of the second switch input terminal B. Under such condition, the ramp signal VRAMP may be correspondingly designed to be increased for gradually raising the voltage level of the first switch input terminal A. Thus, the most proximate voltage levels of the first switch input terminal A and the second switch input terminal B occur at the moment of the voltage level of the first switch input terminal A being higher than the voltage level of the second switch input terminal B. Meanwhile, the high-low relation between the voltage levels of the first exchange output terminal C and the second exchange output terminal D may be also exchanged, which leads to an exchange of the voltage levels of the first comparator output terminal G and the second comparator output terminal H, and means that the voltage difference of the ramp signal VRAMP and the start signal VSTART is approximate or equal to the voltage difference between the brightness voltage VSGN and the initial voltage VRST at this moment.

To sum up above, whether under the first mode or the second mode, the voltage levels of the first comparator output terminal G and the second comparator output terminal H of the amplifier AP1 may exchange for switching the voltage level of the brightness transformation signal BTi when the voltage difference of the ramp signal VRAMP and the start signal VSTART is approximate or equal to the voltage difference between the brightness voltage VSGN or the initial voltage VRST (i.e. input terminal E and the second comparator input terminal F of the amplifier AP1 are substantially the same).

Mathematically speaking, under the first mode, the represented digital code codeᵢ of the brightness transformation signal BT1a can be expressed as codeᵢ=F₁_{ⁱ}(VRST−VSGN)=VRST−VSGN+VOSCMP+VFLICKER(t1) and under the second mode, the represented digital code codeᵢ can be expressed as codeᵢ=G₁_{ⁱ}(VRST−VSGN)=VRST−VSGN−VOSCMP+VFLICKER)(t2), where VOSCMP denotes the voltage offset level of the amplifier AP1, VFLICKER(t1) denotes a flicker noise of the amplifier APT1 during the first period, and VLICKER(t2) denotes a flicker noise of the amplifier APT1 during the second period.

FIG. 2B is a schematic illustrating the driving waveform of the sampling and comparing circuit in accordance an embodiment of the present invention in FIG. 2A. Referring to FIG. 2A and FIG. 2B, in the present embodiment, when the voltage difference of the ramp signal VRAMP and the start signal VSTART is approximate to the voltage difference between the brightness voltage VSGN and the initial voltage VRST, the sampling and comparing circuit SC1a may switch the voltage level of the brightness transformation signal BTi to form a rising edge or a falling edge. Correspondingly, the first latches such as LT11˜LT13 and the second latches such as LT21˜LT23 may be designed to be double-edge triggered, and yet which is not restricted in the present invention.

In the present embodiment, according to the voltage level of the phase signal φ, a first phase period PH1 (corresponding to the phase signal φ at a high voltage level) and a second phase period PH2 (corresponding to the phase signal φ at a low voltage level) may be separated. During the first phase period PH1 of the phase signal φ, the sampling and comparing circuit SC1a is under the first mode; that is, the signal exchanger SE1 controls the first switch input terminal A to couple to the first exchange output terminal C and controls the second switch input terminal B to couple to the second exchange output terminal D according to the phase signal φ; that is, the second terminal of the first capacitor C1 is coupled to the first comparator input terminal E of the amplifier AP1, and the second terminal of the second capacitor C2 is coupled to the second comparator input terminal F of the amplifier AP1.

During a sampling period PSP within the first phase period PH1 of the phase signal φ, the first sampling switch SWS1 and the second sampling switch SWS2 are turned on for providing the reference voltage VR to the first comparator input terminal E and the second comparator input terminal F, and the first comparator switch SWC1 and the second comparator switch SWC2 are turned off. Meanwhile, the first comparator output terminal G and the second comparator output terminal H of the amplifier AP1 outputs a low voltage level (referring to the waveforms VG and VH respectively); that is the brightness transformation signal BTi is at the low voltage level. Also, the brightness voltage switch SWVS and the initial voltage switch SWVR are turned on in sequence for sequentially providing the brightness voltage VSGN to the first terminal of the first capacitor C1 and the initial voltage VRST to the first terminal of the second capacitor C2. Subsequently, the first capacitor C1 samples the brightness voltage VSGN, and the second capacitor C2 samples the initial voltage VRST. The first comparator input terminal E of the amplifier AP1 is coupled to the brightness voltage VSGN via the signal exchanger SE1 and the first capacitor C1; the second comparator input terminal F of the amplifier AP1 is coupled to the initial voltage VRST via the signal exchanger SE1 and the second capacitor C2; wherein, for example, the cross voltage of the first capacitor C1 is higher than that of the second capacitor c2 after the voltage sampling process.

During a comparing period PCP1 within the first phase period PH1 of the phase signal φ, the first sampling switch SWS1, the second sampling switch SWS2, the brightness voltage switch SWVS, and the initial voltage switch SWVR are turned off, and the first comparator switch SWC1 and the second comparator switch SWC2 are turned on for providing the ramp signal VRAMP to the first terminal of the first capacitor C1 and providing the start signal VSTART to the first terminal of the second capacitor C2, wherein, for example, the ramp signal VRAMP is decreased. In this case, the first comparator input terminal E of the amplifier AP1 is coupled to the ramp signal VRAMP via the signal exchanger SE1 and the first capacitor C1, and the second comparator input terminal F of the amplifier AP1 is coupled to the start signal VSTART via the signal exchanger SE1 and the second capacitor C2. The cross voltage of the first capacitor C1 is higher than that of the second capacitor C2, i.e. the voltage level of the first comparator input terminal E is firstly higher than the voltage level of the second comparator input terminal F (referring to the waveforms VE and VF respectively), which leads the first comparator output terminal G to output the high voltage level and the second comparator output terminal H to output the low voltage level.

Then, when the voltage level of the first comparator input terminal E is lower than the voltage level of the second comparator input terminal F affected by the ramp signal VRAMP, the outputted voltage levels of the first comparator output terminal G and the second comparator output terminal H are exchanged; that is, the first comparator output terminal G outputs the low voltage level, and the second comparator output terminal H outputs the high voltage level; that is, the brightness transformation signal BTi switches to the high voltage level to form a rising edge.

During the first phase period PH2 of the phase signal φ, the sampling and comparing circuit SC1a is under the second mode; that is, the signal exchanger SE1 controls the first switch input terminal A to couple to the second exchange output terminal D and controls the second switch input terminal B to couple to the first exchange output terminal C according to the phase signal φ; that is, the second terminal of the first capacitor C1 is coupled to the second comparator input terminal F of the amplifier AP1, and the second terminal of the second capacitor C2 is coupled to the first comparator input terminal E of the amplifier AP1.

During a comparing period PCP2 within the second phase period PH2 of the phase signal φ, the first sampling switch SWS1, the second sampling switch SWS2, the brightness voltage switch SWVS, and the initial voltage switch SWVR are still turned off, and the first comparator switch SWC1 and the second comparator switch SWC2 are still turned on for providing the ramp signal VRAMP to the first terminal of the first capacitor C1 and providing the start signal VSTART to the first terminal of the second capacitor C2, wherein, for example, the ramp signal VRAMP is also decreased. In this case, the first comparator input terminal E of the amplifier AP1 is coupled to the start signal VSTART via the signal exchanger SE1 and the second capacitor C2, and the second comparator input terminal F of the amplifier AP1 is coupled to the ramp signal VRAMP via the signal exchanger SE1 and the first capacitor C1. The cross voltage of the first capacitor C1 is higher than that of the second capacitor C2, i.e. the voltage level of the second comparator input terminal F is firstly higher than the voltage level of the first comparator input terminal E, which leads the first comparator output terminal G to output a low voltage level and the second comparator output terminal H to output a high voltage level.

Then, when the voltage level of the second comparator input terminal F is lower than the voltage level of the first comparator input terminal E affected by the ramp signal VRAMP, the outputted voltage levels of the first comparator output terminal G and the second comparator output terminal H are exchanged; that is, the first comparator output terminal G outputs the high voltage level, and the second comparator output terminal H outputs the low voltage level; that is, the brightness transformation signal BTi switches to the low voltage level to form a falling edge.

To sum up above, under the first mode, the represented digital code codeᵢ of the brightness transformation signal BT1a can be expressed as codeᵢ=F₁_{ⁱ}(VRST−VSGN)=VRST−VSGN+VOSCMP+VFLICKER(t1), and under the second mode, the represented digital code code₁ can be expressed as codeᵢ=G₁_{ⁱ}(VRST−VSGN)=VRST−VSGN−VOSCMP+VFLICKER)(t2), where VOSCMP denotes the voltage offset level of the amplifier AP1, VFLICKER(t1) denotes a flicker noise of the amplifier APT1 during the first period, and VLICKER(t2) denotes a flicker noise of the amplifier APT1 during the second period.

As described above, the brightness value BRVi of the photosensitive pixels PS within the i^{th} column calculated by the arithmetic unit 131 can be expressed as follows: BRVi=H(F₁_{ⁱ}(VRST−VSGN), G₁_{ⁱ}(VRST−VSGN)). Hence, if the arithmetic unit performs a summation operation, the brightness value BRVi is expressed as BRVi=2(VRST−VSGN)+VFLICKER(t1)−VFLICKER(t2). If the arithmetic unit performs an average operation, then the brightness value BRVi is expressed as BRVi=(VRST−VSGN)+(VFLICKER(t1)−VFLICKER(t2))/2. Observable through the above two expressions of brightness value BRVi, the brightness value BRVi generated by the arithmetic unit 131 is able to eliminate the error caused by the voltage offset level of the amplifier AP1. Noteworthily, other expressions H capable of minimizing the voltage level offset of the amplifier AP1 may be derived and adapted. Even, other forms of the brightness value may be obtained by taking the relationship between other functions F and G and the expression H into account.

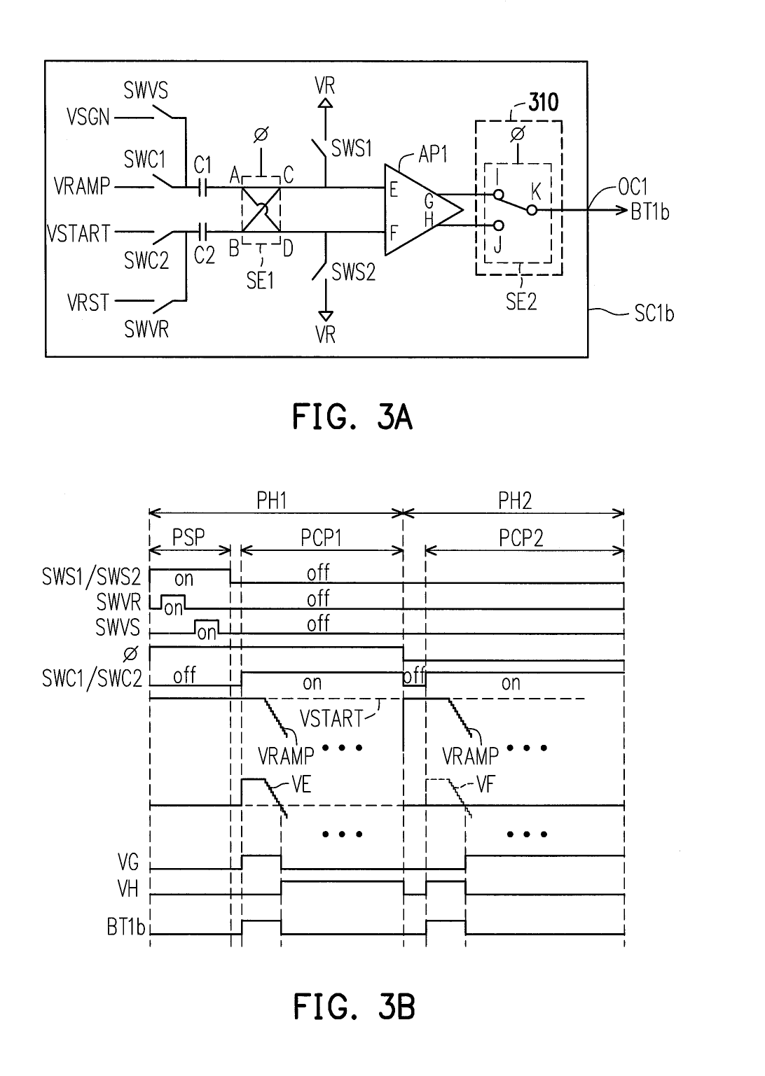

FIG. 3A is a schematic illustrating the sampling and comparing circuits in accordance another embodiment of the present invention in FIG. 1. Referring to FIG. 2A and FIG. 3A, a sampling and comparing circuit SC1b is substantially similar to the sampling and comparing circuit SCi, except for an additional transformation signal generating unit 310.

The transformation signal generating unit 310 may be coupled between the first comparator output terminal G and the second comparator output terminal H of the comparator AP1 and a comparator output terminal OC1 of the sampling and comparing circuit SC1b, and outputs a brightness transformation signal BT1b according to the voltage levels of first comparator output terminal G and the second comparator output terminal H. In other words, when the voltage levels of the first comparator output terminal G and the second comparator output terminal H are exchanged, the transformation signal generating unit 310 may responsively switch the voltage level of the brightness transformation signal BT1b.

The transformation signal generating unit 310 may be designed to generate the brightness transformation signal BT1b according to the voltage level of at least one of the first comparator output terminal G and the second comparator output terminal H in the circuit design. More concretely speaking, in some embodiments, the transformation signal generating unit 310 may be designed to output brightness transformation signal BT1b based on both the voltage levels of the first comparator output terminal G and the second comparator output terminal H. In other embodiments, the signal transformation generation unit 310 may be designed to output the brightness transformation signal BT1b only based on one of the first comparator output terminal G and the second comparator output terminal H.

A detailed structure of the transformation signal generating unit 310 of the embodiment is also illustrated in FIG. 3A. In the present embodiment, the transformation signal generating unit 310 may be achieved by a signal switch SE2. The signal switch SE2 includes a first switch input terminal I, a second switch input terminal J, and an exchange output terminal K. The first switch input terminal I of the signal switch SE2 is coupled to the first comparator output terminal H of the comparator AP1, the second switch input terminal J of the signal switch SE2 is coupled to the second comparator output terminal H of the comparator AP1, and the exchange output terminal K of the signal switch SE2 is coupled to the comparator output terminal OC1 of the sampling and comparing circuit SC1b. The signal switch SE2 receives the phase signal φ and controls the first switch input terminal I or the second switch input terminal J to couple to the exchange output terminal K based on the phase signal φ.

FIG. 3B is a schematic illustrating the driving waveform of the sampling and comparing circuit in accordance with the embodiment of the present invention of FIG. 3A. Referring to FIG. 2A, FIG. 2B, FIG. 3A, and FIG. 3B, the operation of the sampling and comparing circuit SC1b is substantially similar to the sampling and comparing circuit SCi, except for the brightness transformation signal BT1b.

During the first phase period PH1 of the phase signal φ, the signal switch SE2 controls the first switch input terminal I to couple to the exchange output terminal K based on the phase signal φ. Then, when the voltage level of the first comparator input terminal E is lower than the voltage level of the second comparator input terminal F affected by the ramp signal VRAMP, the outputted voltage levels of the first comparator output terminal G and the second comparator output terminal H are exchanged; that is, the first comparator output terminal G outputs low voltage level, and the second comparator output terminal H outputs high voltage level. Meanwhile, the brightness transformation signal BT1b provided by the transformation signal generating unit 310 switches from high voltage level to low voltage level to form a falling edge.

During the second phase period PH2 of the phase signal φ, the signal switch SE2 controls the second switch input terminal J to be coupled to the exchange output terminal K based on the phase signal φ. Then, when the voltage level of the first comparator input terminal E is higher than the voltage level of the second comparator input terminal F affected by the ramp signal VRAMP, the outputted voltage levels of the first comparator output terminal G and the second comparator output terminal H are exchanged; that is, the first comparator output terminal G outputs a high voltage level, and the second comparator output terminal H outputs a low voltage level. Meanwhile, the brightness transformation signal BT1b provided by the transformation signal generating unit 310 switches from the high voltage level to the low voltage level to form a falling edge.

According to the above description, the present embodiment is suitable for the first latches such as LT11˜LT13 and the second latches such as LT21˜LT23 which are falling edge triggered. If the first latches such as LT11˜LT13 and the second latches such as LT21˜LT23 are rising edge triggered, then the embodiment can be correspondingly adjusted such that the second switch input terminal J is coupled to the exchange output terminal K during the first phase period PH1 and the first switch input terminal I is coupled to the exchange output terminal K during the second phase period PH2.

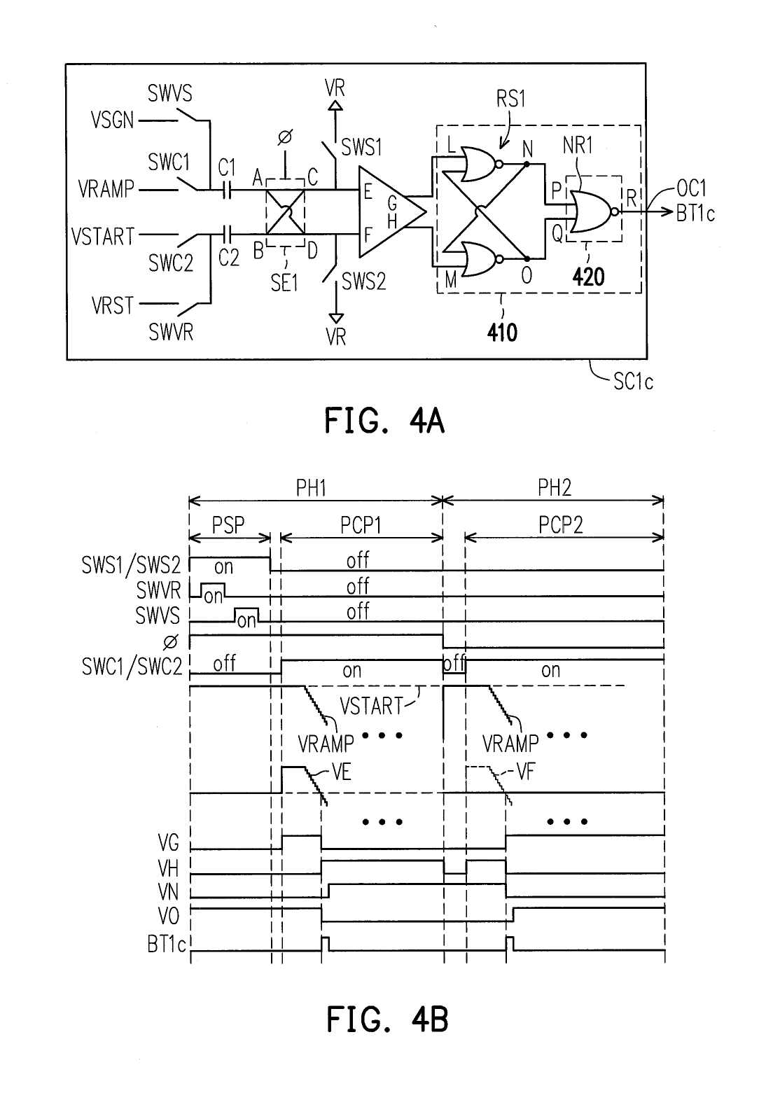

FIG. 4A is a schematic illustrating the sampling and comparing circuits in accordance with another embodiment of the present invention of FIG. 1. Referring to FIG. 3A and FIG. 4A, a sampling and comparing circuit SC1c is substantially similar to the sampling and comparing circuit SC1b, except that a transformation signal generating unit 410 is achieved by a RS latch RS1 and a logic unit 420.

The RS latch RS1 includes a first latch input terminal L, a second latch input terminal M, a first latch output terminal N, and a second latch output terminal O. The logic unit 420 includes a first logic input terminal P, a second logic input terminal Q, and a logic output terminal R. The first latch input terminal L of the RS latch RS1 is coupled to the first comparator output terminal G; the second latch input terminal M of the RS latch RS1 is coupled to the second comparator output terminal H. The first logic input terminal P of the logic unit 420 is coupled to the first latch output terminal N of the RS latch RS1; the second logic input terminal Q of the logic unit 420 is coupled to the second latch output terminal O of the RS latch RS1; the logic output terminal R of the logic unit 420 outputs a brightness transformation signal BT1c, wherein the logic unit 420 switches the voltage level of the logic output terminal R (i.e., switches the voltage level of the brightness transformation signal BT1c) based on the voltage levels of the first logic input terminal P and the second logic input terminal Q.

In the present embodiment, the logic unit 420 includes a NOR gate NR1, wherein a plurality of input terminals of the NOR gate are individually coupled to the first logic input terminal P and the second logic input terminal Q, and an output terminal of the NOR gate is coupled to the logic output terminal R.

FIG. 4B is a schematic illustrating the driving waveform of the sampling and comparing circuits in accordance with the embodiment of the present invention in FIG. 4A. Referring to FIG. 2A, FIG. 2B, FIG. 4A, and FIG. 4B, the operation of the sampling and comparing circuit SC1c is substantially similar to the sampling and comparing circuit SC1b, except for the voltage levels of the first latch output terminal N and the second latch output terminal O of the RS latch RS1 (referring to the waveforms VN and VO respectively) and the brightness transformation signal BT1c.

During the comparing period PCP1 within the first phase period PH1 of the phase signal φ, the first comparator output terminal G firstly outputs a high voltage level and the second comparator output terminal H firstly outputs a low voltage level. Meanwhile, the first latch output terminal N is at a low voltage level and the second latch output terminal O is at a high voltage level. Then, when the voltage level of the first comparator input terminal E is lower than the voltage level of the second comparator input terminal F affected by the ramp signal VRAMP, the outputted voltage levels of the first comparator output terminal G and the second comparator output terminal H are exchanged; that is, the first comparator output terminal G outputs the low voltage level, and the second comparator output terminal H outputs the high voltage level. Meanwhile, controlled by the high voltage level of the second comparator output terminal H, the second latch output terminal O is firstly switched to the low voltage level. Then, the low voltage level of the second latch output terminal O leads the first latch output terminal N to switch to the high voltage level after the feedback. Since the voltage level of first latch output terminal N is switched later than the voltage level of the second latch input terminal O, the first latch output terminal N and the second latch output terminal O are temporarily at the low level voltage, which leads the brightness transformation signal BT1c to form a positive pulse.

During a comparing period PCP2 within the first phase period PH1 of the phase signal φ, the first comparator output terminal G firstly outputs the low voltage level and the second comparator output terminal H firstly outputs the high voltage level. Meanwhile, the first latch output terminal N is at the high voltage level and the second latch output terminal O is at the low voltage level. Then, when the voltage level of the second comparator input terminal F is lower than the voltage level of the first comparator input terminal E affected by the ramp signal VRAMP, the outputted voltage levels of the first comparator output terminal G and the second comparator output terminal H are exchanged; that is, the first comparator output terminal G outputs the high voltage level, and the second comparator output terminal H outputs the low voltage level. Meanwhile, controlled by the low voltage level of the first comparator output terminal G, the first latch output terminal N is firstly switched to the low voltage level. Then, the low voltage level of the first latch output terminal N leads the second latch output terminal O to switch to the high voltage level after the feedback. Since the voltage level of second latch output terminal O is switched later than the voltage level of the first latch input terminal N, the first latch output terminal N and the second latch output terminal O are temporarily at the low level voltage, which leads the brightness transformation signal BT1c to form a positive pulse.

According to the above description, the present embodiment is suitable for the first latches such as LT11˜LT13 and the second latches such as LT21˜LT23 which are high level triggered. If the first latches such as LT11˜LT13 and the second latches such as LT21˜LT23 are low level triggered, then an inverter may be arranged correspondingly between the output terminal of the NOR gate NR1 and the logic output terminal R, or an OR gate may be utilized to achieve the logic unit 420.

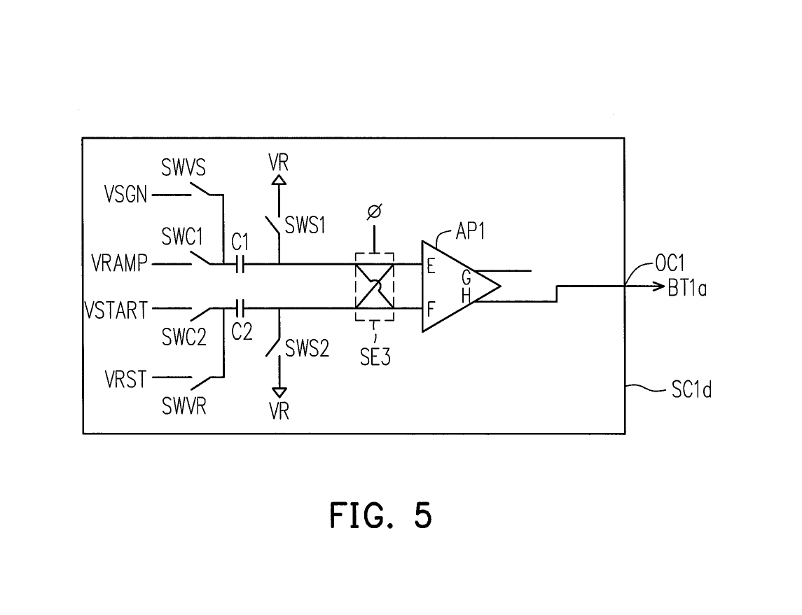

FIG. 5 is a schematic illustrating the sampling and comparing circuits in accordance with an embodiment of the present invention of FIG. 1. Referring to FIG. 2A and FIG. 5, a sampling and comparing circuit SC1d is substantially similar to the sampling and comparing circuit SC1a, except that the position of a signal exchanger SE3 is moved to between the first sampling switch SWS1, the second sampling switch SWS2, and the amplifier AP1, wherein the signal exchanger SE3 can be operated similarly to the signal exchanger SE1. More concretely speaking, the first sampling switch SWS1 is coupled between the second terminal of the first capacitor C1 and the reference voltage VR. The second sampling switch SWS2 is coupled between the second terminal of the second capacitor C2 and the reference voltage VR. The signal exchanger SE3 is coupled between the second terminal of the first capacitor C1, the second terminal of the second capacitor C2, the first comparator input terminal E of the amplifier AP1, and the second comparator input terminal F of the amplifier AP1. In terms of circuit operations, the circuit operation of the sampling and comparing circuit SC1d is identical to the circuit operation of the sampling and comparing circuit SC1a. Related details of other structures and operations may be referred to the description of FIG. 2A and FIG. 2B, which will not be described in any details herein. Similarly, in the embodiment of FIG. 5, a transformation signal generating unit may be added to the back-end block of the amplifier AP1, which extends to another embodiment, and related details of structures and operations may be referred to the description of FIG. 3A to FIG. 4B, which will not be described in any details herein.

Throughout the specification and the appended claims, the term “coupling” refers to any direct or indirect connecting means. For example, if it is described in the text that a first apparatus is coupled to a second apparatus, the intended interpretation is that in some embodiments, the first apparatus may be directly connected to the second apparatus, whereas in some other embodiments, the first apparatus may be indirectly connected to the second apparatus via another apparatus or some kind of connecting means. Additionally, throughout the specification and the appended claims, the term “signal” may indicate a single signal or a plurality of signals.

To sum up above, the image sensor and the column analog-to-digital converter thereof in the embodiments of the present invention generate a brightness transformation signal according to an initial voltage and a brightness voltage of the photosensitive pixels within the corresponding column and a ramp signal and a start signal provided by a ramp signal generator. The first latch latches a counter result provided by a counter according to the corresponding brightness transformation signal so as to output a first brightness latch value during a first period; and the second latch latches a counter result provided by the counter according to the corresponding brightness transformation signal so as to outputs a second brightness latch value during a second period. The arithmetic unit calculates a brightness value of the photosensitive pixel within the corresponding column according to the corresponding first brightness latch value and the corresponding second brightness latch value. Therefore, the effect of the circuit noise can be minimized to improve the accuracy of the detected brightness values.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A column analog-to-digital converter suitable for a pixel array with a plurality of columns of photosensitive pixels, comprising:
a counter for providing a counter result according to a clock signal;
a ramp signal generator for providing a ramp signal and a start signal according to the clock signal;
a sampling and comparing array having a plurality of sampling and comparing circuits, wherein each of the sampling and comparing circuits individually outputs a brightness transformation signal according to the ramp signal, the start signal, and an initial voltage and a brightness voltage of the photosensitive pixels within the corresponding column of the photosensitive pixels;
a first latch array having a plurality of first latches, wherein each of the first latches individually coupled to the counter and latches the counter result as a first brightness latch value in response to the brightness transformation signal outputted from the corresponding sampling and comparing circuit during a first period;
a second latch array having a plurality of second latches, wherein each of the second latches individually coupled to the counter and latches the counter result as a second brightness latch value in response to the brightness transformation signal outputted from the corresponding sampling and comparing circuit during a second period different from the first period; and
an arithmetic unit coupled to the first latch array and the second latch array for receiving the first brightness latch value from each of the first latches and the second brightness latch value from each of the second latches, and calculating a brightness value of the corresponding column of the photosensitive pixels according to the received first brightness latch value and the received second brightness latch value.

2. The column analog-to-digital converter of claim 1, wherein the first period is a first phase period of a phase signal and the second period is a second phase period of the phase signal.

3. The column analog-to-digital converter of claim 1, wherein the arithmetic unit calculates a sum of the received first brightness latch value and the received second brightness latch value as the brightness value of the corresponding column of the photosensitive pixels.

4. The column analog-to-digital converter of claim 1, wherein the arithmetic unit calculates an average of the received first brightness latch value and the received second brightness latch value as the brightness value of the corresponding column of the photosensitive pixels.

5. The column analog-to-digital converter of claim 1, wherein the arithmetic unit comprises a plurality of sub-arithmetic units, wherein each of the sub-arithmetic units is coupled to the corresponding first latch and the corresponding second latch, and the sub-arithmetic units parallel calculate the brightness values of the columns of the photosensitive pixels according to the first brightness latch values from the first latches and the second brightness latch values from the second latches in the same time period.

6. The column analog-to-digital converter of claim 1, wherein the arithmetic unit sequentially calculates the brightness value of each column of the photosensitive pixels individually according to the first brightness latch value from one of the first latches and the second brightness latch value from one of the two latches respectively in different time periods.

7. The column analog-to-digital converter of claim 1, wherein each of the sampling and comparing circuits comprising:
a first comparator switch having a first terminal coupled to the ramp signal and a second terminal;
a second comparator switch having a first terminal coupled to the start signal, and a second terminal;
a first capacitor having a first terminal coupled to the second terminal of the first comparator switch and the brightness voltage, and a second terminal;
a second capacitor having a first terminal coupled to the second terminal of the second comparator switch and the initial voltage, and a second terminal;
an amplifier having a first comparator input terminal, a second comparator input terminal, a first comparator output terminal, and a second comparator output terminal, wherein the brightness transformation signal is generated according to the voltage level of at least one of the first comparator output terminal and the second comparator output terminal;
a signal exchanger coupled between the first capacitor, the second capacitor, and the amplifier for controlling the second terminals of the first capacitor and the second capacitor whether to be coupled to the first comparator input terminal and the second comparator input terminal of the amplifier respectively or to be coupled to the second comparator input terminal and the first comparator input terminal of the amplifier respectively;
a first sampling switch coupled between the first comparator input terminal of the amplifier and a reference voltage; and
a second sampling switch coupled between the second comparator input terminal of the amplifier and the reference voltage.

8. The column analog-to-digital converter of claim 7, further comprising:
a brightness voltage switch coupled between the brightness voltage and the first terminal of the first capacitor; and
an initial voltage switch coupled between the initial voltage and the first terminal of the second capacitor.

9. The column analog-to-digital converter of claim 8, wherein the brightness voltage switch and the initial voltage switch are turned on in sequence during a sampling period within a first phase period of a phase signal and turned off during a comparing period within the first phase period of the phase signal and a second phase period of the phase signal.

10. The column analog-to-digital converter of claim 7, wherein the signal exchanger couples the second terminal of the first capacitor and the second terminal of the second capacitor to the first comparator input terminal and the second comparator input terminal of the amplifier respectively during a comparing period within a first phase period of a phase signal, and the signal exchanger couples the second terminal of the first capacitor and the second terminal of the second capacitor to the second comparator input terminal and the first comparator input terminal of the amplifier respectively during a comparing period within a second phase period of the phase signal.

11. The column analog-to-digital converter of claim 10, wherein the first and the second sampling switches are turned on and the first and the second comparator switches are turned off during a sampling period within the first phase period of the phase signal prior to the comparing period of the first phase period, and the first and the second sampling switches are turned off and the first and the second comparator switches are turned on during the comparing period within the first phase period and the second phase period of the phase signal.

12. The column analog-and-digital converter of claim 7, wherein the first comparator output terminal outputs a first level and the second comparator output terminal outputs a second level when the voltage level of the first comparator input terminal is higher than that of the second comparator input terminal, and the first comparator output terminal outputs the second level and the second comparator output terminal outputs the first level when the voltage level of the first comparator input terminal is lower than or equal to that of the second comparator input terminal.

13. The column analog-to-digital converter of claim 7, wherein each of the sampling and comparing circuits further comprises a transformation signal generating unit coupled between the first comparator output terminal and the second comparator output terminal of the amplifier and a comparator output terminal of the sampling and comparing circuit and outputs the brightness transformation signal according to the voltage levels of the first comparator output terminal and the second comparator output terminal.

14. The column analog-to-digital converter of claim 13, wherein the transformation signal generating unit switches the voltage level of the brightness transformation signal when the voltage levels of the first comparator input terminal and the second comparator input terminal are substantially equal.

15. The column analog-to-digital converter of claim 13, wherein the transformation signal generating unit comprises:
a RS latch having a first latch input terminal coupled to the first comparator output terminal, a second latch input terminal coupled to the second comparator output terminal, a first latch output terminal, and a second latch output terminal.

16. The column analog-to-digital converter of claim 15, wherein the transformation signal generating unit further comprises:
a logic unit having a first logic input terminal coupled to the first latch output terminal, a second logic input terminal coupled to the second latch input terminal, and a logic output terminal, wherein the logic unit switches the voltage level of the logic output terminal based on the voltage levels of the first logic input terminal and the second logic input terminal.

17. The column analog-to-digital converter of claim 16, wherein the logic unit comprises a NOR gate, and wherein a plurality of input terminals of the NOR gate are individually coupled to the first logic input terminal and the second logic input terminal, and wherein an output terminal of the NOR gate is coupled to the logic output terminal.

18. The column analog-to-digital converter of claim 13, wherein the transformation signal generating unit comprises:
a signal switch having a first switch input terminal coupled to the first comparator output terminal of the amplifier, a second switch input terminal coupled to the second comparator output terminal of the amplifier, and an exchange output terminal, wherein the exchange output terminal is coupled to the first switch input terminal during the first period and is coupled to the second switch input terminal during the second period.

19. The column analog-to-digital converter of claim 1, wherein each of the sampling and comparing circuits comprises:
a signal exchanger comprising a first exchange input terminal, a second exchange input terminal, a first exchange output terminal, and a second exchange output terminal, wherein the first exchange input terminal and the second exchange input terminal are coupled to the first exchange output terminal and the second exchange output terminal respectively when the sampling and comparing circuit is operated under the first mode, and the first exchange input terminal and the second exchange input terminal are coupled to the second exchange output terminal and the first output exchange terminal respectively when the sampling and comparing circuit is operated under the second mode; and
an amplifier comprising a first comparator input terminal and a second comparator input terminal coupled to the first exchange output terminal and the second exchange output terminal respectively, and comprising a first comparator output terminal and a second comparator output terminal, wherein the brightness transformation signal is generated based on at least one of the voltage levels of the first comparator output terminal and the second comparator output terminal, wherein
the signal exchanger is operated under the first mode during a sampling period within the first period, so that the first comparator input terminal and the second comparator input terminal coupled to the brightness voltage and the initial voltage respectively,
the signal exchanger is operated under the first mode during a comparing period within the first period, so that the first comparator input terminal and the second comparator input terminal coupled to the ramp signal and the start signal respectively,
the signal exchanger is operated under the second mode during a comparing period within the second period, so that the first comparator input terminal and the second comparator input terminal coupled to the start signal and the ramp signal respectively.

20. The column analog-to-digital converter of claim 19, wherein each of the sampling and comparing circuits further comprises:
a first capacitor having a first terminal and a second terminal, wherein the second terminal is coupled to the first exchange input terminal;
a second capacitor having a first terminal and a second terminal, wherein the second terminal is coupled to the second exchange input terminal;
a first comparator switch coupled between the ramp signal and the first terminal of the first capacitor; and
a second comparator switch coupled between the start signal and the first terminal of the second capacitor.

21. The column analog-to-digital converter of claim 20, wherein each of the sampling and comparing circuits further comprises:
a brightness voltage switch coupled between the brightness voltage and the first terminal of the first capacitor; and
an initial voltage switch coupled between the initial voltage and the first terminal of the second capacitor.

22. The column analog-to-digital converter of claim 19, wherein each of the sampling and comparing circuits further comprises:
a first sampling switch coupled between the first comparator input terminal of the amplifier and a reference voltage; and
a second sampling switch coupled between the second comparator input terminal of the amplifier and the reference voltage.

23. The column analog-to-digital converter of claim 19, wherein the sampling and comparing array is operated under the first mode and the second mode during the first period and the second period respectively, and wherein the brightness transformation signal and the brightness voltage have different functional relationships under the first mode and the second mode.

24. An image sensor comprising:
a pixel array having a plurality of columns of photosensitive pixels; and
a column analog-to-digital converter as claim 1 coupled to the pixel array.
